(19) United States
(12) Patent Application Publication
(10) Pub. No.: US 2025/0185466 A1
(43) Pub. Date: Jun. 5, 2025

(54) DISPLAY DEVICE AND METHOD OF FABRICATING THE SAME

(71) Applicant: Samsung Display Co., LTD., Yongin-si (KR)

(72) Inventors: In Kyung YOO, Yongin-si (KR); Young Seok BAEK, Yongin-si (KR); Jin Seok SEO, Yongin-si (KR); Mi Jung HAN, Yongin-si (KR)

(73) Assignee: Samsung Display Co., LTD., Yongin-si (KR)

(21) Appl. No.: 18/774,278

(22) Filed: Jul. 16, 2024

(30) Foreign Application Priority Data
Nov. 30, 2023 (KR) 10-2023-0170744

(51) Int. Cl. H10K 59/122; H10K 59/12; H10K 59/131; H10K 59/80

(52) U.S. Cl. CPC H10K 59/122; H10K 59/1201; H10K 59/131; H10K 59/873

(57) ABSTRACT

A display device includes a pixel defining layer defining a first opening; a bank structure defining a second opening; a residual pattern between an anode and the pixel defining layer in the second opening; a light emitting layer on the anode and contacting the bank structure; a cathode on the light emitting layer and contacting the bank structure; a power line on the non-display area of the substrate; a dam structure disposed on the power line; and a power connection electrode on the power line and the dam structure and spaced apart from the anode, a portion of the power connection electrode is covered by the residual pattern and the pixel defining layer, and a side surface of the power connection electrode facing the dam structure contacts the residual pattern and is completely covered by the residual pattern and the pixel defining layer.

### CROSS-REFERENCE TO RELATED APPLICATION(S)

This application claims the benefit of and priority to Korean Patent Application No. 10-2023-0170744 under 35 U.S.C. § 119, filed on Nov. 30, 2023, in the Korean Intellectual Property Office, the entire contents of which are incorporated herein by reference.

### BACKGROUND

### 1. Technical Field

The disclosure relates to a display device and a method of fabricating the same.

### 2. Description of the Related Art

As the information society develops, demands for display devices for displaying images are increasing in various forms. For example, display devices are applied to various electronic devices such as smartphones, digital cameras, notebook computers, navigation devices, and smart televisions. The display devices may be flat panel display devices such as liquid crystal display devices, field emission display devices, and organic light emitting display devices. Among these flat panel display devices, a light emitting display device may include a light emitting element that enables each pixel of a display panel to emit light by itself. Thus, the light emitting display device can display an image without a backlight unit that provides light to the display panel.

With the recent development of various electronic devices, the demand for high-resolution display devices is increasing. Since high-resolution display devices are required to have a high pixel density, a gap between light emitting elements respectively overlapping emission areas may be reduced. Therefore, a high-resolution display device may be formed by a pattern process for forming individual pixels rather than a process using a fine metal mask.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Aspects of the disclosure provide a display device including a bank structure disposed in a display area and a non-display area and solve corrosion defects of a power connection electrode connected to a first power electrode in a portion overlapping the non-display area.

However, aspects of the disclosure are not restricted to the ones set forth herein. The above and other aspects of the disclosure will become more apparent to one of ordinary skill in the art to which the disclosure pertains by referencing the detailed description of the disclosure given below.

According to an aspect of the disclosure, a display device may include a display area which may include an emission area and a non-emission area and a non-display area surrounding the display area; a substrate; an anode disposed on the emission area of the substrate; a pixel defining layer disposed on the non-emission area of the substrate and defining a first opening; a bank structure disposed on the pixel defining layer and defining a second opening; a residual pattern disposed between the anode and the pixel defining layer in the second opening in a direction perpendicular to the substrate; a light emitting layer disposed on the anode and contacting the bank structure; a cathode disposed on the light emitting layer and contacting the bank structure; a power line disposed on the non-display area of the substrate; a dam structure disposed on the power line; and a power connection electrode disposed on the power line and the dam structure and spaced apart from the anode, wherein a portion of the power connection electrode is covered by the residual pattern and the pixel defining layer, and a side surface of the power connection electrode facing the dam structure contacts the residual pattern and is completely covered by the residual pattern and the pixel defining layer.

In an embodiment, the bank structure may include a first bank layer contacting the cathode; and a second bank layer comprising a tip protruding more toward the emission area than a side surface of the first bank layer facing the first opening.

In an embodiment, the residual pattern overlapping the non-display area may comprise a first side surface overlapping the power line in a direction perpendicular to the substrate, and the first side surface contacts the first bank layer and is completely covered by the first bank layer.

In an embodiment, the residual pattern overlapping the display area and the residual pattern overlapping the non-display area may be spaced apart from each other.

In an embodiment, the residual pattern overlapping the display area may overlap the tip of the second bank layer in the direction perpendicular to the substrate.

In an embodiment, in a portion overlapping the non-display area, the pixel defining layer may be disposed between the first bank layer and the residual pattern in the direction perpendicular to the substrate.

In an embodiment, the pixel defining layer overlapping the non-display area may include a first side surface overlapping the power line in the direction perpendicular to the substrate, and the first side surface contacts the first bank layer and is completely covered by the first bank layer.

In an embodiment, the pixel defining layer overlapping the display area and the pixel defining layer overlapping the non-display area may be spaced apart from each other.

In an embodiment, the residual pattern and the pixel defining layer overlapping the non-display area may completely cover the dam structure.

In an embodiment, the side surface of the power connection electrode facing the dam structure may be completely covered by the bank structure, and the bank structure completely covers the dam structure.

In an embodiment, the power connection electrode may include a first surface facing the bank structure, and the first surface comprises a first part contacting the residual pattern and a second part contacting the first bank layer.

In an embodiment, the first surface may be completely covered by the residual pattern and the first bank layer.

In an embodiment, the first part overlaps the pixel defining layer and the bank structure in the direction perpendicular to the substrate, and the second part may do not overlap the pixel defining layer and the residual pattern in the direction perpendicular to the substrate.

In an embodiment, a voltage applied to the power line may be applied to the cathode through the power connection electrode and the first bank layer.

In an embodiment, the display may comprise an organic pattern disposed on the tip of the second bank layer, the organic pattern and the light emitting layer comprising a same material, and spaced apart from the light emitting layer; and an electrode pattern disposed on the organic pattern, the electrode pattern and the cathode comprising a same material, and spaced apart from the cathode.

In an embodiment, the display may comprise a thin-film encapsulation layer on the cathode, the electrode pattern and the bank structure, wherein the thin-film encapsulation layer overlaps the display area and the non-display area and comprises at least one organic material layer and at least one inorganic material layer.

According to an aspect of the disclosure, a display device may include a display area comprising an emission area and a non-emission area and a non-display area surrounding the display area; a substrate; a pixel defining layer disposed on the non-emission area of the substrate and defining a first opening; a bank structure disposed on the pixel defining layer and defining a second opening; a power line disposed on the non-display area of the substrate and surrounding the display area; a dam structure disposed on the power line and surrounding the display area; and a power connection electrode covering the power line and the dam structure, wherein a residual pattern and a pixel defining layer are disposed between the bank structure and the power connection electrode in a direction perpendicular to the substrate, and the bank structure disposed in the non-emission area and the bank structure disposed in the non-display area are integral in plan view.

In an embodiment, the bank structure may completely cover the power connection electrode and the dam structure in plan view.

In an embodiment, the second opening may completely surround the first opening in plan view, and the bank structure completely surrounds the second opening in plan view.

According to an aspect of the disclosure, a method of fabricating a display device, the method may include forming a substrate comprising a display area and a non-display area surrounding the display area, forming a power line on the substrate of the non-display area, forming a dam structure and a power connection electrode, connected to the power line, on the power line, and forming a sacrificial layer covering entire surfaces of the power connection electrode and the dam structure; forming a photoresist around the dam structure, exposing a portion of the power connection electrode again by removing a portion of the sacrificial layer by performing a first etching process, and forming a pixel defining material layer on the entire surfaces of the sacrificial layer and the power connection electrode; forming a photoresist around the dam structure, exposing a portion of the power connection electrode again by removing a portion of the pixel defining material layer by performing a second etching process, and forming a bank structure on entire surfaces of the pixel defining material layer and the power connection electrode; and forming a mask in a portion overlapping the dam structure and the power connection electrode and forming a pixel defining layer and a residual pattern, covering a portion of the power connection electrode and the dam structure, by removing the bank structure, the pixel defining material layer and the sacrificial layer in an exposed portion by performing a third etching process, wherein a side surface of the power connection electrode facing the dam structure contacts the residual pattern, and the power connection electrode is completely covered by the residual pattern and the bank structure.

It should be noted that effects of the disclosure are not limited to those described above and other effects of the disclosure will be apparent to those skilled in the art from the following descriptions.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic perspective view of an electronic device according to an embodiment;

FIG. 2 is a schematic perspective view of a display device included in the electronic device according to the embodiment;

FIG. 3 is a schematic cross-sectional view illustrating a schematic side view of the display device of FIG. 2;

FIG. 4 is a schematic plan view of a display layer of FIG. 3;

FIG. 5 is a schematic plan view illustrating the arrangement of emission areas in a display area of FIG. 4;

FIG. 6 is a schematic cross-sectional view taken along line X1-X1′ of FIG. 5;

FIG. 7 is an enlarged schematic cross-sectional view of a first emission area in FIG. 6;

FIG. 8 is an enlarged schematic plan view of part A of FIG. 4;

FIG. 9 is a schematic cross-sectional view taken along line X3-X3′ of FIG. 8;

FIG. 10 is an enlarged schematic cross-sectional view of a portion overlapping a power connection electrode in FIG. 9;

FIG. 11 is a schematic plan view of structures overlapping a bank structure in FIG. 8; and

FIGS. 12 through 18 are schematic cross-sectional views illustrating a process of fabricating a display device according to an embodiment in a non-display area of FIG. 9.

### DETAILED DESCRIPTION OF THE EMBODIMENTS

In the following description, for the purposes of explanation, numerous details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in an embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (for example, as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (for example, rotated 90 degrees or at other orientations), and, as such, the spatially relative descriptors used herein interpreted accordingly.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terminology used herein is for the purpose of describing given embodiments and is not intended to be limiting. As used herein, the singular forms, “a,” “an,” and “the” are intended to include the plural forms as well, unless the context clearly indicates otherwise.

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (for example, microcode) to perform various functions discussed herein and may optionally be driven by firmware and/or software. It is also contemplated that each block, unit, and/or module may be implemented by dedicated hardware, or as a combination of dedicated hardware to perform some functions and a processor (for example, one or more programmed microprocessors and associated circuitry) to perform other functions. Also, each block, unit, and/or module of some embodiments may be physically separated into two or more interacting and discrete blocks, units, and/or modules without departing from the scope of the disclosure. Further, the blocks, units, and/or modules of some embodiments may be physically combined into more complex blocks, units, and/or modules without departing from the scope of the disclosure.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments will be described in detail with reference to the accompanying drawings.

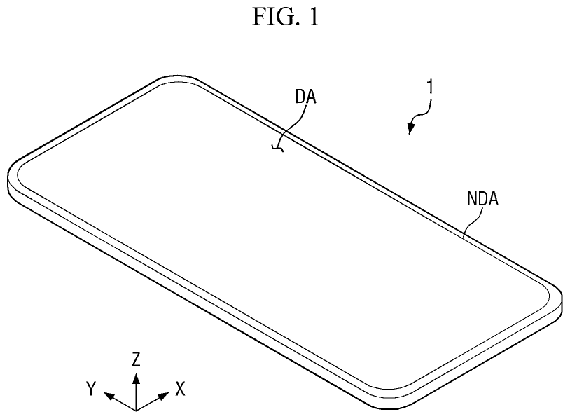

FIG. 1 is a schematic perspective view of an electronic device 1 according to an embodiment.

Referring to FIG. 1, the electronic device 1 displays moving images or still images. The electronic device 1 may refer to any electronic device that provides a display screen. Examples of the electronic device 1 may include televisions, notebook computers, monitors, billboards, Internet of things (IoT) devices, mobile phones, smartphones, tablet personal computers (PCs), electronic watches, smart watches, watch phones, head mounted displays, mobile communication terminals, electronic notebooks, electronic books, portable multimedia players (PMPs), navigation devices, game machines, digital cameras and camcorders, all of which provide a display screen.

In FIG. 1, a first direction (X-axis direction), a second direction (Y-axis direction), and a third direction (Z-axis direction) are defined. The first direction (X-axis direction) and the second direction (Y-axis direction) may be perpendicular to each other, the first direction (X-axis direction) and the third direction (Z-axis direction) may be perpendicular to each other, and the second direction (Y-axis direction) and the third direction (Z-axis direction) may be perpendicular to each other. It may be understood that the first direction (X-axis direction) refers to a horizontal direction in the drawing, the second direction (Y-axis direction) refers to a vertical direction in the drawing, and the third direction (Z-axis direction) refers to an up-down direction in the drawing, for example, a thickness direction. In the following specification, unless otherwise specified, a “direction” may refer to both directions extending to both sides along the direction. In addition, when it is necessary to distinguish both “directions” extending to both sides, one side or a side will be referred to as a “first side in the direction,” and the other side or another side will be referred to as a “second side in the direction.” Based on FIG. 1, a direction in which an arrow is directed will be referred to as the first side, and a direction opposite to the direction will be referred to as the second side.

Hereinafter, for ease of description, in referring to surfaces of the electronic device 1 or each member constituting the electronic device 1, one surface or a surface facing the first side in a direction in which an image is displayed, for example, in the third direction (Z-axis direction) will be referred to as an upper surface, and the other surface or another surface opposite the one surface or a surface will be referred to as a lower surface. However, the disclosure is not limited thereto, and the one surface or a surface and the other surface or another surface of each member may also be referred to as a front surface and a rear surface or as a first surface and a second surface, respectively. In addition, in describing relative positions of the members of the electronic device 1, the first side in the third direction (Z-axis direction) may be referred to as an upper side, and the second side in the third direction (Z-axis direction) may be referred to as a lower side.

The shape of the electronic device 1 can be variously modified. For example, the electronic device 1 may have various shapes such as a horizontally long rectangle, a vertically long rectangle, a square, a quadrilateral with rounded corners (vertices), other polygons, and a circle.

The electronic device 1 may include a display area DA and a non-display area NDA. The display area DA is an area where a screen can be displayed, and the non-display area NDA is an area where no screen is displayed. The display area DA may also be referred to as an active area, and the non-display area NDA may also be referred to as an inactive area. The display area DA may generally occupy a center of the electronic device 1.

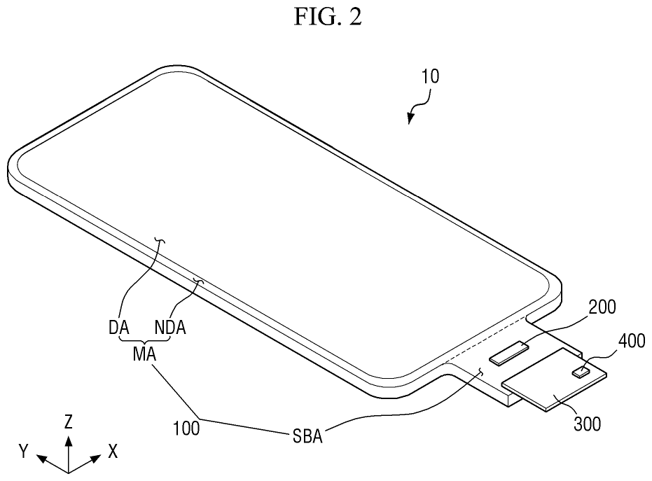

FIG. 2 is a schematic perspective view of a display device 10 included in the electronic device 1 according to the embodiment.

Referring to FIG. 2, the electronic device 1 according to the embodiment may include the display device 10. The display device 10 may provide a screen that is displayed by the electronic device 1. The display device 10 may be, for example, an inorganic light emitting diode display device, an organic light emitting display device, a quantum dot light emitting display device, a plasma display panel, or a field emission display device. A case where an organic light emitting diode display device is applied as an example of the display device 10 will be described below, but the disclosure is not limited to this case, and other display devices can also be applied in the same technical spirit.

The planar shape of the display device 10 may be similar to that of the electronic device 1. For example, the planar shape of the display device 10 may be similar to a rectangle having short sides in the first direction (X-axis direction) and long sides in the second direction (Y-axis direction). Each corner where a short side extending in the first direction (X-axis direction) meets a long side extending in the second direction (Y-axis direction) may be rounded with a selectable curvature. However, the disclosure is not limited thereto, and each corner may also be right-angled. The planar shape of the display device 10 is not limited to a quadrilateral shape but may also be similar to other polygonal shapes, a circular shape, or an oval shape.

The display device 10 may include a display panel 100, a display driver 200, a circuit board 300, and a touch driver 400.

The display panel 100 may include a main area MA and a sub-area SBA. The main area MA may include a display area DA including pixels that display an image and a non-display area NDA disposed around the display area DA.

The display area DA may emit light from emission areas or openings which will be described later. The non-display area NDA may be an area outside the display area DA. The non-display area NDA may be defined as an edge area of the main area MA of the display panel 100.

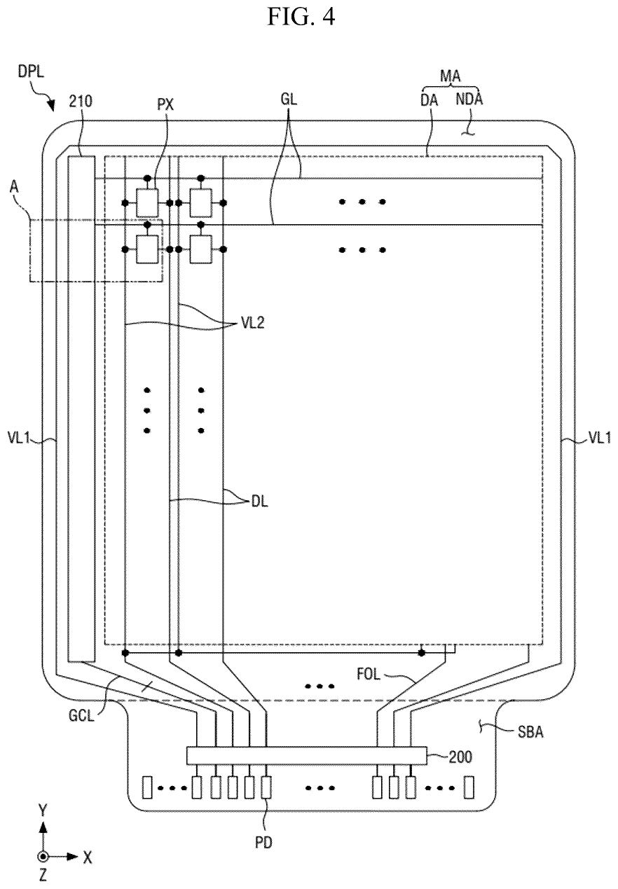

The sub-area SBA may be an area extending from a side of the main area MA. The sub-area SBA may include a flexible material that can be bent, folded, rolled, etc. For example, in case that the sub-area SBA is bent, it may be overlapped by the main area MA in the thickness direction (for example, the third direction (Z-axis direction)). The sub-area SBA may include the display driver 200 and display pads PD (see FIG. 4) connected to the circuit board 300. In an embodiment, the sub-area SBA may be omitted, and the display driver 200 and the display pads PD may be located (or disposed) in the non-display area NDA.

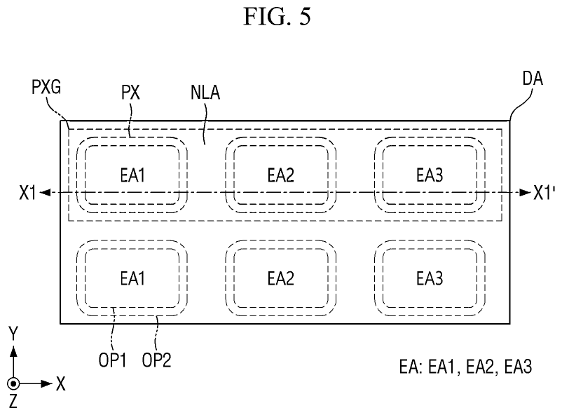

The display driver 200 may output signals and voltages for driving the display panel 100. The display driver 200 may supply data voltages to data lines DL (see FIG. 4) which will be described later. The display driver 200 may supply a power supply voltage to power lines VL1 and VL2 (see FIG. 4) and supply a gate control signal to a gate driver 210 (see FIG. 5). The display driver 200 may be formed as an integrated circuit and mounted on the display panel 100 using a chip on glass (COG) method, a chip on plastic (COP) method, or an ultrasonic bonding method. For example, the display driver 200 may be disposed in the sub-area SBA and may be overlapped by the main area MA in the thickness direction by the bending of the sub-area SBA. For another example, the display driver 200 may be mounted on the circuit board 300.

The circuit board 300 may be attached onto the display pads PD of the display panel 100 using an anisotropic conductive film. The circuit board 300 may be electrically connected to the display pads PD. The circuit board 300 may be a flexible printed circuit board, a printed circuit board, or a flexible film such as a chip on film.

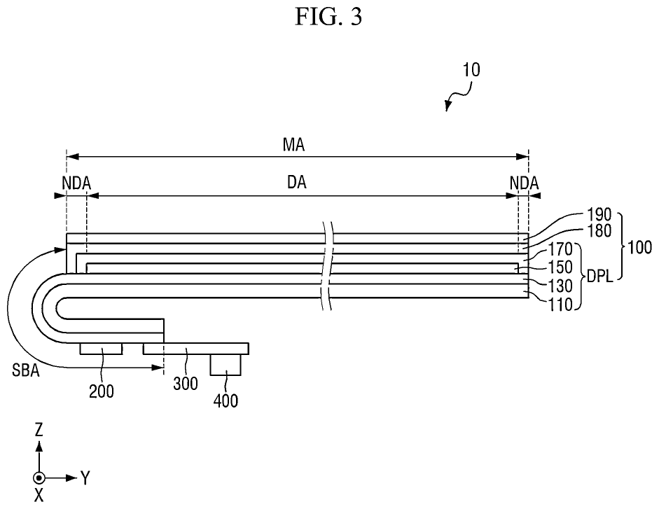

The touch driver 400 may be mounted on the circuit board 300. The touch driver 400 may be connected to a touch senor layer 180 (see FIG. 3) of the display panel 100.

FIG. 3 is a schematic cross-sectional view of the display device 10 of FIG. 2.

Referring to FIG. 3, the display panel 100 may include a display layer DPL, the touch sensor layer 180, and a color filter layer 190. The display layer DPL may include a substrate 110, a thin-film transistor layer 130, a display element layer 150, and a thin-film encapsulation layer 170.

The substrate 110 may be a base substrate or a base member. The substrate 110 may be a flexible substrate that can be bent, folded, rolled, etc. For example, the substrate 110 may include polymer resin such as polyimide (PI). However, the disclosure is not limited thereto. In an embodiment, the substrate 110 may include a glass material or a metal material.

The thin-film transistor layer 130 may be disposed on the substrate 110. The thin-film transistor layer 130 may be disposed in the display area DA, the non-display area NDA, and the sub-area SBA. The thin-film transistor layer 130 may include thin-film transistors constituting pixels PX (see FIG. 4).

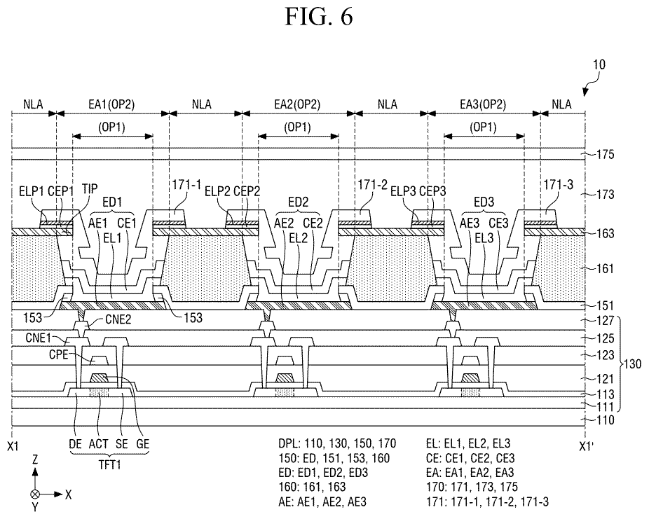

The display element layer 150 may be disposed on the thin-film transistor layer 130. The display element layer 150 may overlap the display area DA. The display element layer 150 may include light emitting elements ED (see FIG. 6).

The thin-film encapsulation layer 170 may be located on the display element layer 150. The thin-film encapsulation layer 170 may overlap the display area DA and the non-display area NDA. The thin-film encapsulation layer 170 may cover upper and side surfaces of the display element layer 150 and may protect the display element layer 150 from external oxygen and moisture. The thin-film encapsulation layer 170 may include at least one inorganic layer and at least one organic layer to encapsulate the display element layer 150.

The touch sensor layer 180 may be disposed on the thin-film encapsulation layer 170. The touch sensor layer 180 may overlap the display area DA and the non-display area NDA. The touch sensor layer 180 may sense a user's touch using a mutual capacitance method or a self-capacitance method.

The color filter layer 190 may be disposed on the touch sensor layer 180. The color filter layer 190 may overlap the display area DA and the non-display area NDA. The color filter layer 190 may absorb some of the light incident from the outside of the display device 10, thereby reducing reflected light caused by the external light. Therefore, the color filter layer 190 can prevent color distortion caused by the reflection of external light.

Since the color filter layer 190 is directly disposed on the touch sensor layer 180, the display device 10 may not require a separate substrate for the color filter layer 190. Therefore, a thickness of the display device 10 may be relatively small. The color filter layer 190 can be omitted depending on embodiments.

As illustrated in FIG. 3, a portion of the display layer DPL which overlaps the sub-area SBA may be bent. In case that a portion of the display layer DPL is bent, the display driver 200, the circuit board 300, and the touch driver 400 may be overlapped by the main area MA in the third direction (Z-axis direction).

FIG. 4 is a schematic plan view of the display layer DPL of FIG. 3.

Referring to FIG. 4, the display layer DPL included in an embodiment may overlap the display area DA of the main area MA and include pixels PX, gate lines GL, data lines DL, and second power lines VL2.

Each of the pixels PX may be defined as a smallest unit that emits light. The pixels PX may respectively form first through third emission areas EA1 through EA3 which will be described later.

The gate lines GL may supply gate signals received from the gate driver 210 to the pixels PX. The gate lines GL may extend in the first direction (X-axis direction) and may be spaced apart from each other in the second direction (Y-axis direction) intersecting the first direction (X-axis direction).

The data lines DL may supply data voltages received from the display driver 200 to the pixels PX. The data lines DL may extend in the second direction (Y-axis direction) and may be spaced apart from each other in the first direction (X-axis direction).

The second power lines VL2 may supply a power supply voltage received from the display driver 200 to the pixels PX. Here, the power supply voltage may be at least one of a driving voltage, an initialization voltage, and a reference voltage. The second power lines VL2 may extend in the second direction (Y-axis direction) and may be spaced apart from each other in the first direction (X-axis direction).

The display layer DPL included in an embodiment may overlap the non-display area NDA of the main area MA and include a first power line VL1, the gate driver 210, fan-out lines FOL, and a gate control line GCL.

The gate driver 210 may generate gate signals based on a gate control signal and sequentially supply the gate signals to the gate lines GL in a set order.

The first power line VL1 may be disposed in the non-display area NDA to surround the display area DA. The first power line VL1 may supply a power supply voltage received from the display driver 200 to the pixels PX. The first power line VL1 may be electrically connected to various lines located in the display area DA.

The fan-out lines FOL may extend from the display driver 200 to the display area DA. The fan-out lines FOL may supply data voltages received from the display driver 200 to the data lines DL.

The gate control line GCL may extend from the display driver 200 to the gate driver 210. The gate control line GCL may supply a gate control signal received from the display driver 200 to the gate driver 210. Although the gate driver 210 is disposed only in the non-display area NDA located on a left side of the display area DA in the drawing, the disclosure is not limited thereto. In an embodiment, the display device 10 may include gate drivers 210 disposed on left and right sides of the display area DA, respectively.

The display layer DPL included in an embodiment may include the display driver 200 and display pads PD in the sub-area SBA.

The display driver 200 may output signals and voltages for driving the pixels PX to the fan-out lines FOL. The display driver 200 may supply data voltages to the data lines DL through the fan-out lines FOL. Accordingly, the data voltages may be supplied to the pixels PX and may control luminances of the pixels PX. The display driver 200 may supply a gate control signal to the gate driver 210 through the gate control lines GCL.

The display pads PD may be connected to a graphics system through the circuit board 300. The display pads PD may be connected to the circuit board 300 to receive digital video data and may supply the digital video data to the display driver 200.

FIG. 5 is a schematic plan view illustrating the arrangement of emission areas EA in the display area DA.

Referring to FIG. 5, the display area DA of an embodiment may include first through third emission areas EA1 through EA3 and a non-emission area NLA. The non-emission area NLA may surround the first through third emission areas EA1 through EA3.

The non-emission area NLA may block light emitted from each of the first through third emission areas EA1 through EA3. Therefore, the non-emission area NLA may help prevent the color mixing of light emitted from the first through third emission areas EA1 through EA3. A pixel defining layer 151 (see FIG. 6) and a bank structure 160 (see FIG. 6), which will be described later, may be disposed in the non-emission area NLA.

The emission areas EA may include the first emission areas EA1, the second emission areas EA2, and the third emission areas EA3 which emit light of different colors. Each of the first through third emission areas EA1 through EA3 may emit red, green, or blue light. The color of light emitted from each of the first through third emission areas EA1 through EA3 may vary according to the type of light emitting element ED which will be described later. For example, the first emission areas EA1 may emit red light of a first color, the second emission areas EA2 may emit green light of a second color, and the third emission areas EA3 may emit blue light of a third color, but the disclosure is not limited thereto. Although the first through third emission areas EA1 through EA3 have the same size and shape in the drawing, the disclosure is not limited thereto. The size and shape of each of the first through third emission areas EA1 through EA3 can be freely adjusted according to required characteristics.

The first through third emission areas EA1 through EA3 may be defined by first openings OP1 and second openings OP2. For example, the first openings OP1 may be defined by the pixel defining layer 151 (see FIG. 6) which will be described later, and the second openings OP2 may be defined by the bank structure 160 (see FIG. 6) which will be described later. The second openings OP2 may completely surround the first openings OP1 in plan view. The second openings OP2 may be completely surrounded by the non-emission area NLA in plan view.

In an embodiment, at least one first emission area EA1, at least one second emission area EA2, and at least one third emission area EA3 disposed adjacent to each other may form one pixel group PXG. The pixel group PXG may be a smallest unit that emits white light. However, the types and/or number of the first through third emission areas EA1 through EA3 constituting the pixel group PXG may vary according to embodiments.

FIG. 6 is a schematic cross-sectional view taken along line X1-X1′ of FIG. 5. FIG. 6 illustrates a schematic cross section of the display layer DPL overlapping the display area DA. For example, FIG. 6 illustrates cross sections of the substrate 110, the thin-film transistor layer 130, the display element layer 150, and the thin-film encapsulation layer 170 of the display device 10 according to an embodiment. Since the substrate 110 has already been mentioned, a redundant description thereof will be omitted.

Referring to FIG. 6, the thin-film transistor layer 130 may be located on the substrate 110. The thin-film transistor layer 130 may include a first buffer layer 111, first thin-film transistors TFT1, a gate insulating layer 113, a first interlayer insulating layer 121, capacitor electrodes CPE, a second interlayer insulating layer 123, first connection electrodes CNE1, a first via layer 125, second connection electrodes CNE2, and a second via layer 127.

The first buffer layer 111 may be disposed on the substrate 110. The first buffer layer 111 may include an inorganic layer that can prevent the penetration of air or moisture. For example, the first buffer layer 111 may include inorganic layers stacked alternately each other.

The first thin-film transistors TFT1 may be disposed on the first buffer layer 111 and may constitute pixel circuits respectively connected to pixels. For example, each of the first thin-film transistors TFT1 may be a driving transistor or a switching transistor of a pixel circuit. Each of the first thin-film transistors TFT1 may include an active layer ACT, a source electrode SE, a drain electrode DE, and a gate electrode GE.

The active layer ACT may be disposed on the first buffer layer 111. The active layer ACT may be overlapped by the gate electrode GE in the third direction (Z-axis direction) and may be insulated from the gate electrode GE by the gate insulating layer 113. The material of the active layer ACT may be made conductive in portions of the active layer ACT to form the source electrode SE and the drain electrode DE.

The gate electrode GE may be disposed on the gate insulating layer 113. The gate electrode GE may overlap the active layer ACT with the gate insulating layer 113 interposed between them.

The gate insulating layer 113 may be disposed on the active layers ACT. The gate insulating layer 113 may cover the active layers ACT and the first buffer layer 111 and may insulate the active layers ACT from the gate electrodes GE. The gate insulating layer 113 may include contact holes through which the first connection electrodes CNE1 pass.

The first interlayer insulating layer 121 may cover the gate electrodes GE and the gate insulating layer 113. The first interlayer insulating layer 121 may include contact holes through which the first connection electrodes CNE1 pass. The contact holes of the first interlayer insulating layer 121 may be connected to the contact holes of the gate insulating layer 113 and contact holes of the second interlayer insulating layer 123.

The capacitor electrodes CPE may be disposed on the first interlayer insulating layer 121. The capacitor electrodes CPE may overlap the gate electrodes GE in the third direction (Z-axis direction). The capacitor electrodes CPE and the gate electrodes GE may form capacitance.

The second interlayer insulating layer 123 may cover the capacitor electrodes CPE and the first interlayer insulating layer 121. The second interlayer insulating layer 123 may include the contact holes through which the first connection electrodes CNE1 pass. The contact holes of the second interlayer insulating layer 123 may be connected to the contact holes of the first interlayer insulating layer 121 and the contact holes of the gate insulating layer 113.

The first connection electrodes CNE1 may be disposed on the second interlayer insulating layer 123. The first connection electrodes CNE1 may electrically connect the drain electrodes DE of the first thin-film transistors TFT1 to the second connection electrodes CNE2. The first connection electrodes CNE1 may be inserted into the contact holes formed in the first interlayer insulating layer 121, the second interlayer insulating layer 123 and the gate insulating layer 113 to contact the drain electrodes DE of the first thin-film transistors TFT1.

The first via layer 125 may cover the first connection electrodes CNE1 and the second interlayer insulating layer 123. The first via layer 125 may flatten structures thereunder. The first via layer 125 may include contact holes through which the second connection electrodes CNE2 pass.

The second connection electrodes CNE2 may be disposed on the first via layer 125. The second connection electrodes CNE2 may be inserted into the contact holes formed in the first via layer 125 to contact the first connection electrodes CNE1. The second connection electrodes CNE2 may electrically connect the first connection electrodes CNE1 to anodes AE.

The second via layer 127 may cover the second connection electrodes CNE2 and the first via layer 125. The second via layer 127 may include contact holes through which the anodes AE pass.

The display element layer 150 may be disposed on the thin-film transistor layer 130. The display element layer 150 may include light emitting elements ED, the pixel defining layer 151, residual patterns 153, and the bank structure 160.

Each of the light emitting elements ED may include an anode AE, a light emitting layer EL, and a cathode CE. The light emitting elements ED may include a first light emitting element ED1 disposed in a first emission area EA1, a second light emitting element ED2 disposed in a second emission area EA2, and a third light emitting element ED3 disposed in a third emission area EA3.

The first through third light emitting elements ED1 through ED3 may emit light of different colors depending on the materials of first through third light emitting layers EL1 through EL3. For example, the first light emitting element ED1 may emit red light of the first color, the second light emitting element ED2 may emit green light of the second color, and the third light emitting element ED3 may emit blue light of the third color.

The anodes AE may be disposed on the second via layer 127. The anodes AE may be electrically connected to the drain electrodes DE of the first thin-film transistors TFT1 through the first connection electrodes CNE1 and the second connection electrodes CNE2.

The anodes AE may include a first anode AE1 disposed in the first emission area EA1, a second anode AE2 disposed in the second emission area EA2, and a third anode AE3 disposed in the third emission area EA3. The first anode AE1, the second anode AE2, and the third anode AE3 may be spaced apart from each other on the second via layer 127.

In an embodiment, the anodes AE may have a stacked structure of a material layer having a high work function such as indium-tin-oxide (ITO), indium-zinc-oxide (IZO), zinc oxide (ZnO) or indium oxide (In₂O₃) and a reflective material layer such as silver (Ag), magnesium (Mg), aluminum (Al), platinum (Pt), lead (Pb), palladium (Pd), gold (Au), nickel (Ni), neodymium (Nd), iridium (Ir), chromium (Cr), lithium (Li), or a mixture thereof. For example, the anodes AE may have, but are not limited to, a multilayer structure of ITO/Mg, ITO/MgF, ITO/Ag, or ITO/Ag/ITO.

The pixel defining layer 151 may be located on the second via layer 127 and the anodes AE. As described above, the pixel defining layer 151 may define the first openings OP1 that form the emission areas EA. The pixel defining layer 151 may be disposed on the entire surface of the second via layer 127, but may partially expose upper surfaces of the anodes AE. For example, the pixel defining layer 151 may expose the anodes AE in portions overlapping the first openings OP1, and the light emitting layers EL may be directly disposed on the anodes AE in the portions overlapping the first openings OP1.

The pixel defining layer 151 may include an inorganic insulating material. For example, the pixel defining layer 151 may include aluminum oxide, titanium oxide, tantalum oxide, hafnium oxide, zinc oxide, silicon oxide, silicon nitride, or silicon oxynitride.

The bank structure 160 may be located on the pixel defining layer 151. The bank structure 160 may define the second openings OP2 that form the emission areas EA. The light emitting elements ED of the display device 10 may overlap the second openings OP2. The bank structure 160 may include a first bank layer 161 and a second bank layer 163 including different metal materials and structures and playing different roles. The bank structure 160 will be described later.

The light emitting layers EL may be disposed on the anodes AE. The light emitting layers EL may be organic light emitting layers made of an organic material and may be formed on the anodes AE through a deposition process. In case that a first thin-film transistor TFT1 applies a selectable voltage to an anode AE and a cathode CE receives a common voltage or a cathode voltage, holes and electrons may move to a light emitting layer EL through a hole transport layer and an electron transport layer, respectively, and may be combined with each other in the light emitting layer EL to emit light.

The light emitting layers EL may include the first light emitting layer EL1 disposed in the first emission area EA1, the second light emitting layer EL2 disposed in the second emission area EA2, and the third light emitting layer EL3 disposed in the third emission area EA3. For example, the first light emitting layer EL1 may be a light emitting layer that emits red light of the first color, the second light emitting layer EL2 may be a light emitting layer that emits green light of the second color, and the third light emitting layer EL3 may be a light emitting layer that emits blue light of the third color. However, the disclosure is not limited thereto.

In an embodiment, the anodes AE may be spaced apart from the pixel defining layer 151 in the third direction (Z-axis direction). The light emitting layers EL and the residual patterns 153 may be located between the anodes AE and the pixel defining layer 151 spaced apart from each other. The residual patterns 153 may be residues of a temporary protective layer which is temporarily formed on the anodes AE and removed during a process of fabricating the display device 10.

The cathodes CE may include a transparent conductive material to transmit light generated from the light emitting layers EL. The cathodes CE may receive a common voltage or a low-potential voltage. In case that an anode AE receives a voltage corresponding to a data voltage and a cathode CE receives a low-potential voltage, a potential difference may be formed between the anode AE and the cathode CE. Accordingly, a light emitting layer EL may emit light.

In an embodiment, the cathodes CE may include a material layer having a small work function such as Li, Ca, LiF/Ca, LiF/Al, Al, Mg, Ag, Pt, Pd, Ni, Au Nd, Ir, Cr, BaF, Ba, or a compound or mixture thereof (for example, a mixture of Ag and Mg). The cathodes CE may further include a transparent metal oxide layer disposed on the material layer having a small work function.

The cathodes CE may include a first cathode CE1, a second cathode CE2, and a third cathode CE3 disposed in the first emission area EA1, the second emission area EA2, and the third emission area EA3, respectively. The first cathode CE1 may be disposed on the first light emitting layer EL1 in the first emission area EA1, the second cathode CE2 may be disposed on the second light emitting layer EL2 in the second emission area EA2, and the third cathode CE3 may be disposed on the third light emitting layer EL3 in the third emission area EA3.

The first cathode CE1, the second cathode CE2, and the third cathode CE3 may be spaced apart from each other. The cathodes CE spaced apart from each other may not be directly connected but may be electrically connected through the first bank layer 161 of the bank structure 160.

First through third organic patterns ELP1 through ELP3 and first through third electrode patterns CEP1 through CEP3 may be disposed on the bank structure 160 to surround the first openings OP1.

The first through third organic patterns ELP1 through ELP3 may be located on the second bank layer 163. The first through third organic patterns ELP1 through ELP3 may include the same material as the first through third light emitting layers EL1 through EL3, respectively. The first organic pattern ELP1 may include the same material as the first emitting layer EL1, the second organic pattern ELP2 may include the same material as the second emitting layer EL2, and the third organic pattern ELP3 may include the same material as the third light emitting layer EL3. The first through third organic patterns ELP1 through ELP3 may be traces formed as the first through third light emitting layers EL1 through EL3 are separated by tips TIP included in the bank structure 160.

The first through third electrode patterns CEP1 through CEP3 may be disposed on the first through third organic patterns ELP1 through ELP3. The arrangement relationship between the first through third electrode patterns CEP1 through CEP3 and the first through third organic patterns ELP1 through ELP3 may be the same as the arrangement relationship between the first through third light emitting layers EL1 through EL3 and the first through third cathodes CE1 through CE3. The first through third electrode patterns CEP1 through CEP3 may include the same material as the first through third cathodes CE1 through CE3. The first through third electrode patterns CEP1 through CEP3 may be traces formed as the first through third cathodes CE1 through CE3 are separated by the tips TIP included in the bank structure 160.

The thin-film encapsulation layer 170 may be disposed on the display element layer 150. The thin-film encapsulation layer 170 may include at least one inorganic layer to prevent oxygen or moisture from penetrating into the display element layer 150. The thin-film encapsulation layer 170 may include at least one organic layer to protect the display element layer 150 from foreign substances such as dust.

In an embodiment, the thin-film encapsulation layer 170 may include a first encapsulation layer 171, a second encapsulation layer 173, and a third encapsulation layer 175 stacked sequentially. The first encapsulation layer 171 and the third encapsulation layer 175 may be inorganic encapsulation layers, and the second encapsulation layer 173 disposed between them may be an organic encapsulation layer.

The first encapsulation layer 171 may include first through third inorganic layers 171-1 through 171-3. The first through third inorganic layers 171-1 through 171-3 may cover the light emitting elements ED and the bank structure 160. The first through third inorganic layers 171-1 through 171-3 may be formed through a chemical vapor deposition (CVD) process. Therefore, the first through third inorganic layers 171-1 through 171-3 may be formed to a uniform thickness along the profiles of structures thereunder.

The first through third inorganic layers 171-1 through 171-3 may overlap the first through third emission areas EA1 through EA3, respectively. For example, the first inorganic layer 171-1 may overlap the first emission area EA1 to cover the first cathode CE1 and the first electrode pattern CEP1, the second inorganic layer 171-2 may overlap the second emission area EA2 to cover the second cathode CE2 and the second electrode pattern CEP2, and the third inorganic layer 171-3 may overlap the third emission area EA3 to cover the third cathode CE3 and the third electrode pattern CEP3. The first through third inorganic layers 171-1 through 171-3 may overlap the non-emission area NLA to expose the bank structure 160 and may be spaced apart from each other.

Although the first through third inorganic layers 171-1 through 171-3 are formed on the same layer in the drawing, they may be formed in different processes. For example, the first inorganic layer 171-1 may be formed after the first cathode CE1 is formed, the second inorganic layer 171-2 may be formed after the second cathode CE2 is formed, and the third inorganic layer 171-3 may be formed after the third cathode CE3 is formed.

The first encapsulation layer 171 may include one or more inorganic insulating materials. The inorganic insulating materials may include aluminum oxide (Al₂O₃), titanium oxide (Ti₂O₃), tantalum oxide (Ta₂O₅), hafnium oxide (HfO₂), zinc oxide (ZnO), silicon oxide (SiO₂), silicon nitride (Si₃N₄), and silicon oxynitride (Si₂N₂O).

The second encapsulation layer 173 may be located on the first encapsulation layer 171. The second encapsulation layer 173 may flatten steps formed by the first encapsulation layer 171.

The second encapsulation layer 173 may include a polymer-based material. Examples of the polymer-based material may include acrylic resin, epoxy resin, polyimide, and polyethylene. For example, the second encapsulation layer 173 may include acrylic resin such as polymethyl methacrylate or polyacrylic acid. The second encapsulation layer 173 may be formed by curing a monomer or applying a polymer.

The third encapsulation layer 175 may be located on the second encapsulation layer 173. The third encapsulation layer 175 may include the same material as the first encapsulation layer 171. The third encapsulation layer 175 may prevent oxygen or moisture from penetrating into the second encapsulation layer 173.

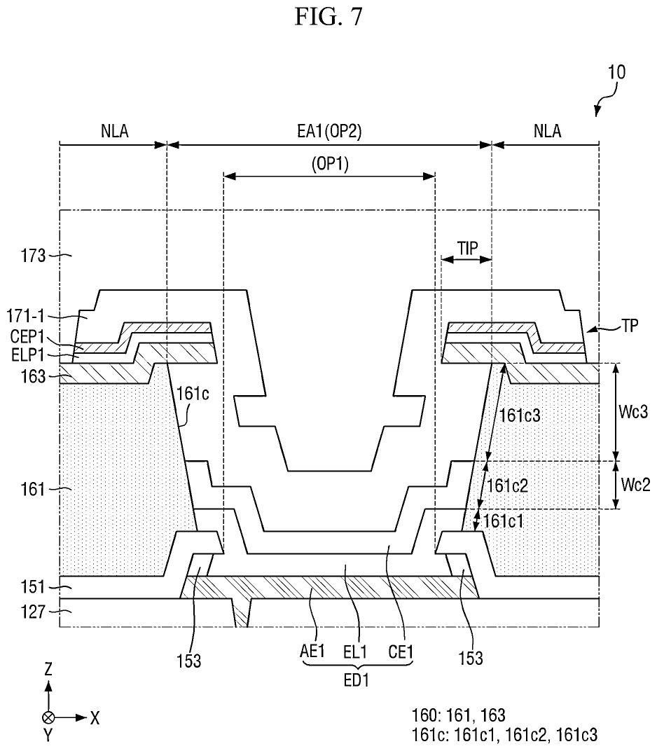

FIG. 7 is an enlarged schematic cross-sectional view of the first emission area EA1 in FIG. 6.

Referring to FIG. 7, the pixel defining layer 151 may be located on the second via layer 127 and the first anode AE1. The pixel defining layer 151 may overlap a second opening OP2 and may be spaced apart from the first anode AE1 in the third direction (Z-axis direction), and a residual pattern 153 may be located between the pixel defining layer 151 and the first anode AE1. The residual pattern 153 may contact both sides of the first light emitting layer EL1 in the first direction (X-axis direction) and may be overlapped by the tips TIP of the bank structure 160 in the third direction (Z-axis direction).

The bank structure 160 may be located on the pixel defining layer 151. The bank structure 160 may include the first bank layer 161 and the second bank layer 163 including different metal materials and structures and playing different roles.

The first bank layer 161 may be located on the pixel defining layer 151 to contact the pixel defining layer 151. The first bank layer 161 may include a metal having high electrical conductivity, for example, aluminum (Al).

In an embodiment, the first bank layer 161 may include side surfaces 161c facing a first opening OP1. The side surfaces 161c of the first bank layer 161 may be inclined surfaces. In other words, the side surfaces 161c of the first bank layer 161 may be inclined between the first direction (X-axis direction) and the third direction (Z-axis direction). For example, the side surfaces 161c of the first bank layer 161 may be more recessed than the pixel defining layer 151 in the first direction (X-axis direction).

The first light emitting layer EL1 and the first cathode CE1 may contact the side surfaces 161c of the first bank layer 161 of an embodiment. Since the bank structure 160 may include the tips TIP in the display device 10 according to the embodiment, the first light emitting layer EL1 and the first cathode CE1 can be formed through a deposition and photo pattern process without using a fine metal mask in a fabrication process. Therefore, the first light emitting layer EL1 and the first cathode CE1 may contact the side surfaces 161c of the first bank layer 161 in a portion overlapping the second opening OP2.

The first cathode CE1 of an embodiment may cover more of the side surfaces 161c of the first bank layer 161 than the first light emitting layer EL1. As described above, the first cathode CE1 and the first bank layer 161 may be electrically connected. Here, the electrical resistance of the display device 10 may decrease as the area of contact between the first cathode CE1 and each side surface 161c of the first bank layer 161 increases.

In an embodiment, each of the side surfaces 161c of the first bank layer 161 may include a first part 161c1, a second part 161c2, and a third part 161c3 depending on a structure that it contacts. The first part 161c1 may be a part in contact with the first light emitting layer EL1, the second part 161c2 may be a part in contact with the first cathode CE1, and the third part 161c3 may be a part in contact with the first inorganic layer 171-1.

The second part 161c2 may be disposed between the first part 161c1 and the third part 161c3, and the area Wc2 of the second part 161c2 may be adjusted according to a method of fabricating the first cathode CE1. As the area Wc2 of the second part 161c2 is adjusted, the area Wc3 of the third part 161c3 may also be adjusted. For example, in case that the area Wc2 of the second part 161c2 increases, the area Wc3 of the third part 161c3 may decrease.

The second bank layer 163 of an embodiment may be located on the first bank layer 161. The second bank layer 163 may include a material having a lower etch rate than that of the first bank layer 161. For example, the second bank layer 163 may include titanium (Ti). The second bank layer 163 may have the tips TIP that protrude more than the side surfaces 161c of the first bank layer 161 toward the first emission area EA1. Since the second bank layer 163 may include the tips TIP in the display device 10 according to the embodiment, the first light emitting element ED1 can be formed without a fine metal mask in the process of fabricating the display device 10. Other redundant descriptions may be omitted.

The first organic pattern ELP1 may be located on the second bank layer 163. The first organic pattern ELP1 may be located in portions overlapping the protruding tips TIP of the second bank layer 163 within the second opening OP2. The first organic pattern ELP1 may cover the second bank layer 163 in a portion overlapping the non-emission area NLA.

In the fabrication process of the display device 10, the first organic pattern ELP1 may be formed to cover the entire surface of the second bank layer 163 and may be partially etched in a subsequent etching process. Trench portions TP may be formed on side surfaces of the etched first organic pattern ELP1. The trench portions TP may be covered by the second encapsulation layer 173.

The first electrode pattern CEP1 may be located on the first organic pattern ELP1. The first electrode pattern CEP1 may be located in the portions overlapping the protruding tips TIP of the second bank layer 163 within the second opening OP2. The first electrode pattern CEP1 may cover the first organic pattern ELP1 in the portion overlapping the non-emission area NLA.

In the fabrication process of the display device 10, the first electrode pattern CEP1 may be formed to cover the entire surface of the first organic pattern ELP1 and may be partially etched in a subsequent etching process. The trench portions TP may be formed on side surfaces of the etched first electrode pattern CEP1. The trench portions TP may be covered by the second encapsulation layer 173.

The first inorganic layer 171-1 may cover the first light emitting element ED1 and the first electrode pattern CEP1. The first inorganic layer 171-1 may be disposed within the second opening OP2 to contact the first cathode CE1 and the side surfaces 161c of the first bank layer 161 and cover the protruding tips TIP of the second bank layer 163. The first inorganic layer 171-1 may cover the first electrode pattern CEP1 in the portion overlapping the non-emission area NLA.

In the fabrication process of the display device 10, the first inorganic layer 171-1 may be formed to cover the entire surface of the first electrode pattern CEP1 and may be partially etched in a subsequent etching process. The trench portions TP may be formed in the etched portions of the first inorganic layer 171-1. The trench portions TP may be covered by the second encapsulation layer 173.

The second encapsulation layer 173 may flatten steps formed by the first inorganic layer 171-1 in a portion overlapping the first opening OP1 and may cover the first inorganic layer 171-1 and the second bank layer 163 in portions overlapping the second opening OP2 and the non-emission area NLA. Other redundant descriptions may be omitted.

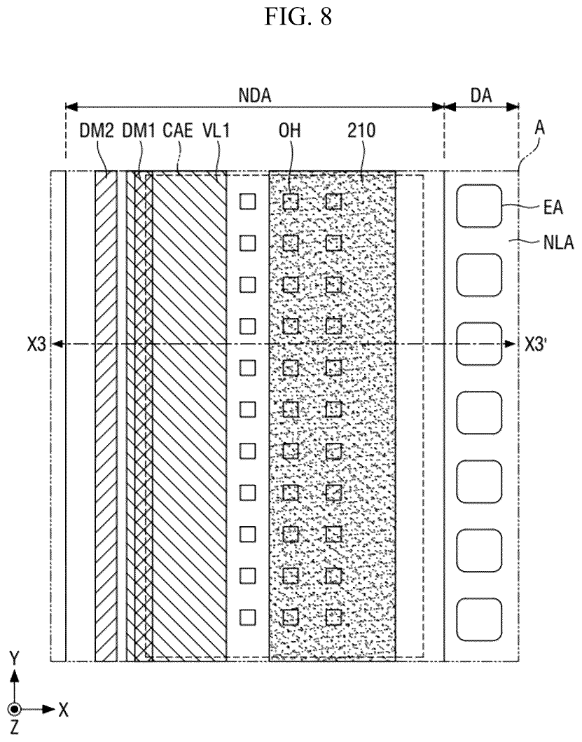

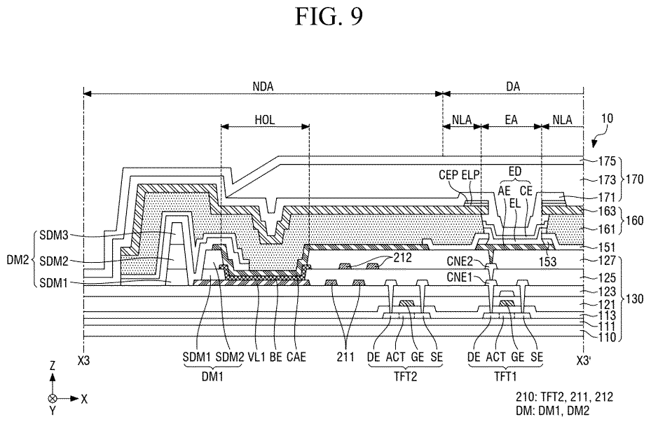

FIG. 8 is an enlarged schematic plan view of part A of FIG. 4. FIG. 9 is a schematic cross-sectional view taken along line X3-X3′ of FIG. 8.

Referring to FIGS. 8 and 9, the display device 10 according to the embodiment may include a light emitting element ED overlapping an emission area EA of the display area DA and the bank structure 160 overlapping the non-emission area NLA. The display device 10 may include the gate driver 210, the first power line VL1, hole patterns OH, a power connection electrode CAE, and a dam structure DM in a portion overlapping the non-display area NDA. A redundant description of the structures overlapping the emission area EA and the non-emission NLA will be omitted.

The gate driver 210 may be disposed in the portion overlapping the non-display area NDA and may be disposed between a first thin-film transistor TFT1 and the first power line VL1. The gate driver 210 may include a second thin-film transistor TFT2 and gate driving electrodes 211 and 212. The second thin-film transistor TFT2 may be disposed on the first buffer layer 111 and may form a driving circuit of the gate driver 210. The second thin-film transistor TFT2 may have the same structure and characteristics as the first thin-film transistor TFT1. For example, the second thin-film transistor TFT2 may include an active layer ACT, a source electrode SE, a drain electrode DE, and a gate electrode GE. The gate electrode GE may be disposed on the gate insulating layer 113 and may overlap the active layer ACT with the gate insulating layer 113 interposed between them.

First gate driving electrodes 211 may be disposed on the second interlayer insulating layer 123. The first gate driving electrodes 211 may be disposed on the same layer as a first connection electrode CNE1 of the display area DA. The first gate driving electrodes 211 may serve as connection electrodes in a circuit that drives the gate driver 210.

Second gate driving electrodes 212 may be disposed on the first via layer 125. The second gate driving electrodes 212 may be disposed on the same layer as a second connection electrode CNE2 of the display area DA. The second gate driving electrodes 212 may serve as connection electrodes in the circuit that drives the gate driver 210.

The first power line VL1 may be disposed outside the gate driver 210 in the portion overlapping the non-display area NDA. The first power line VL1 may be disposed on the second interlayer insulating layer 123, and a portion of an upper surface of the first power line VL1 may be exposed through a hole penetrating the first via layer 125 and the second via layer 127. The exposed upper surface of the first power line VL1 may contact a connection electrode BE.

The hole patterns OH may be disposed between the gate driver 210 and the first power line VL1, and some of the hole patterns OH may overlap the gate driver 210. The hole patterns OH may form paths through which gas generated from the first via layer 125 and the second via layer 127 is released during the fabrication process of the display device 10.

The connection electrode BE may be disposed in the portion overlapping the non-display area NDA and may be disposed on the first power line VL1. Although not illustrated in the drawings, the connection electrode BE may extend to surround the display area DA in a shape similar to that of the first power line VL1 in plan view. The connection electrode BE may not overlap the gate driver 210 and may be disposed outside the gate driver 210.

The connection electrode BE may be disposed on the first via layer 125 and may directly contact the first power line VL1 through a hole penetrating the first via layer 125. The connection electrode BE may be disposed between the first power line VL1 and the power connection electrode CAE to serve as a bridge that electrically connect them.

The power connection electrode CAE may be disposed in the portion overlapping the non-display area NDA and may overlap the gate driver 210, the connection electrode BE, and the first power line VL1. As illustrated in FIG. 8, the power connection electrode CAE may completely cover the first power line VL1 and the gate driver 210 in plan view.

The power connection electrode CAE may be disposed on the second via layer 127 and may be disposed on the same layer as an anode AE of the display area DA. The power connection electrode CAE may be spaced apart from the anode AE with the pixel defining layer 151 interposed between them in the first direction (X-axis direction).

The power connection electrode CAE may directly contact the connection electrode BE in a portion overlapping a hole HOL that penetrates the first via layer 125 and the second via layer 127. The power connection electrode CAE may be disposed between the connection electrode BE and the first bank layer 161 to serve as a bridge that electrically connects them to each other. For example, the power connection electrode CAE may be electrically connected to the first power line VL1. Therefore, a voltage applied through the first power line VL1 may be transmitted to a cathode CE disposed in the emission area EA through the connection electrode BE, the power connection electrode CAE, and the first bank layer 161.

The dam structure DM of an embodiment may include a first dam DM1 and a second dam DM2. The first dam DM1 and the second dam DM2 may be disposed in the portion overlapping the non-display area NDA and may surround the display area DA in plan view. The first dam DM1 may be disposed close to the display area DA to surround the display area DA in plan view, and the second dam DM2 may surround the first dam DM1 in plan view. The first dam DM1 and the second dam DM2 may prevent the second encapsulation layer 173 from overflowing.

In an embodiment, the first dam DM1 may include a first sub-dam SDM1 and a second sub-dam SDM2, and the second dam DM2 may include a first sub-dam SDM1, a second sub-dam SDM2, and a third sub-dam SDM3. The first sub-dam SDM1 may include the same material as the first via layer 125 and may be disposed on the same layer as the first via layer 125. The second sub-dam SDM2 may include the same material as the second via layer 127 and may be disposed on the same layer as the second via layer 127. The third sub-dam SDM3 may be disposed on the second sub-dam SDM2 and may include the same material as the second sub-dam SDM2. The third sub-dam SDM3 may be located at the same height as the pixel defining layer 151 disposed in the display area DA. In an embodiment, the third sub-dam SDM3 may include the same material as the pixel defining layer 151.

In an embodiment, a height of the first dam DM1 may be lower than a height of the second dam DM2. However, the disclosure is not limited thereto. The height of the first dam DM1 may also be substantially the same as the height of the second dam DM2 or may also be higher than the height of the second dam DM2.

A residual pattern 153 may be disposed on the dam structure DM and the power connection electrode CAE in the portion overlapping the non-display area NDA. The residual pattern 153 of an embodiment may be disposed on the power connection electrode CAE in the portion overlapping the hole HOL that penetrates the first via layer 125 and the second via layer 127 and may extend to lie on the dam structure DM. A portion of the residual pattern 153 of the embodiment may contact the power connection electrode CAE, and the other portion of the residual pattern 153 may contact the dam structure DM.

The residual pattern 153 overlapping the display area DA and the residual pattern 153 overlapping the non-display area NDA may be formed integrally during the fabrication process of the display device 10, but may be separated from each other as a portion of the residual pattern 153 is removed by a subsequent etching process. Therefore, the residual pattern 153 overlapping the display area DA and the residual pattern 153 overlapping the non-display area NDA may include the same material and may be spaced apart from each other.

The pixel defining layer 151 of an embodiment may be disposed on the residual pattern 153 in the portion overlapping the non-display area NDA. The pixel defining layer 151 overlapping the display area DA and the pixel defining layer 151 overlapping the non-display area NDA may be spaced apart from each other in the first direction (X-axis direction). The pixel defining layer 151 of the embodiment may completely cover the power connection electrode CAE and the dam structure DM in the portion overlapping the non-display area NDA.

The bank structure 160 may be disposed on the power connection electrode CAE and the pixel defining layer 151 in the portion overlapping the non-display area NDA. The bank structure 160 overlapping the display area DA and the bank structure 160 overlapping the non-display area NDA may be integral. However, as illustrated in FIG. 9, in cross section, portions of the bank structure 160 may be spaced apart from each other in the first direction (X-axis direction) with the light emitting element ED interposed between them in a portion overlapping the display area DA.

In the portion overlapping the non-display area NDA, the first bank layer 161 may completely cover the power connection electrode CAE and the pixel defining layer 151 and may contact the power connection electrode CAE and the pixel defining layer 151. In the portion overlapping the non-display area NDA, the first bank layer 161 may completely cover the gate driver 210, the connection electrode BE, the first power line VL1, the residual pattern 153, the first dam DM1, and the second dam DM2 in the third direction (Z-axis direction).

In the portion overlapping the non-display area NDA, the second bank layer 163 may cover the first bank layer 161 along the profile of the first bank layer 161. In the portion overlapping the non-display area NDA, the second bank layer 163 may overlap the gate driver 210, the power connection electrode CAE, the connection electrode BE, the first power line VL1, the residual pattern 153, the pixel defining layer 151, the first dam DM1, and the second dam DM2 in the third direction (Z-axis direction).

The first encapsulation layer 171 of an embodiment may cover the light emitting element ED, an organic pattern ELP, and an electrode pattern CEP in the portion overlapping the display area DA and may extend to cover the second bank layer 163 along the profile of the second bank layer 163 in the portion overlapping the non-display area NDA. The first encapsulation layer 171 may cover the dam structure DM and extend to an outermost edge of the display device 10. Other redundant descriptions may be omitted.

The second encapsulation layer 173 of an embodiment may flatten steps formed by the first encapsulation layer 171 in the portion overlapping the display area DA and may extend to lie in a portion overlapping a portion of the first dam DM1 in the portion overlapping the non-display area NDA. The second encapsulation layer 173 of the embodiment may be prevented from overflowing to the outside of the display device 10 by a step of the bank structure 160 formed to overlap the second dam DM2.

The third encapsulation layer 175 of an embodiment may cover the second encapsulation layer 173 and the first encapsulation layer 171 along the profiles of the second encapsulation layer 173 and the first encapsulation layer 171. The third encapsulation layer 175 of the embodiment may cover the dam structure DM and may extend to the outermost edge of the display device 10. Other redundant descriptions may be omitted.

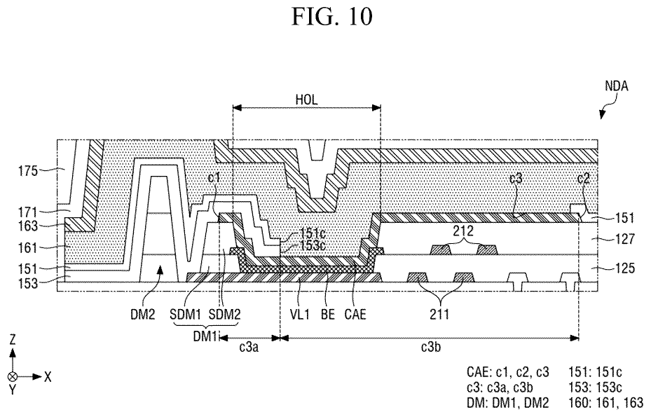

FIG. 10 is an enlarged schematic cross-sectional view of a portion overlapping the power connection electrode CAE in FIG. 9.

Referring to FIG. 10, the power connection electrode CAE of an embodiment may include a first side surface c1, a second side surface c2, and an upper surface c3. The first side surface c1 of an embodiment may be disposed in a portion overlapping the first dam DM1 or in a direction toward the dam structure DM and may contact the residual pattern 153 overlapping the non-display area NDA. Since the first side surface c1 of the power connection electrode CAE of the embodiment is completely covered by the residual pattern 153 and the pixel defining layer 151, it is possible to solve corrosion defects caused by penetration of an etchant during the fabrication process of the display device 10.

The second side surface c2 of an embodiment may be located opposite the first side surface c1 and may contact the pixel defining layer 151. The second side surface c2 of the embodiment may be completely covered by the pixel defining layer 151 overlapping the non-display area NDA.

The upper surface c3 of an embodiment may be disposed in a direction toward the bank structure 160 and may contact the first bank layer 161 and the residual pattern 153. The upper surface c3 of the embodiment may be divided into a first part c3a and a second part c3b depending on a structure that it contacts. The first part c3a may contact the residual pattern 153 and may overlap the pixel defining layer 151 and the bank structure 160 in the third direction (Z-axis direction). The second part c3b may contact the first bank layer 161 and may not overlap the pixel defining layer 151 and the residual pattern 153 in the third direction (Z-axis direction).

In an embodiment, the residual pattern 153 overlapping the non-display area NDA of an embodiment may include a side surface 153c in a portion overlapping the hole HOL. The residual pattern 153 overlapping the non-display area NDA may be formed to cover the entire upper surface c3 of the power connection electrode CAE during the fabrication process of the display device 10 and may be partially removed by a subsequent etching process to form the shape illustrated in FIG. 10. The side surface 153c included in the residual pattern 153 may be formed as a result of performing the above etching process. The side surface 153c of the residual pattern 153 may contact the first bank layer 161 and may be completely covered by the first bank layer 161.

In an embodiment, the pixel defining layer 151 overlapping the non-display area NDA of the embodiment may include a side surface 151c in the portion overlapping the hole HOL. The pixel defining layer 151 overlapping the non-display area NDA may be formed to cover the entire upper surface c3 of the power connection electrode CAE during the fabrication process of the display device 10 and may be partially removed by a subsequent etching process to form the shape illustrated in FIG. 10. The side surface 151c included in the pixel defining layer 151 may be formed as a result of performing the above etching process. The side surface 151c of the pixel defining layer 151 may contact the first bank layer 161 and may be completely covered by the first bank layer 161. The fabrication process will be described later.

The first bank layer 161 overlapping the non-display area NDA of the embodiment may contact the upper surface c3 of the power connection electrode CAE, the side surface 153c of the residual pattern 153 and the side surface 151c of the pixel defining layer 151 and may completely cover the upper surface c3 of the power connection electrode CAE, the side surface 153c of the residual pattern 153 and the side surface 151c of the pixel defining layer 151. Since the first bank layer 161 of the embodiment contacts and covers the upper surface c3 of the power connection electrode CAE, it is possible to solve corrosion defects of the power connection electrode CAE caused by penetration of an etchant during the fabrication process of the display device 10. Other redundant descriptions may be omitted.

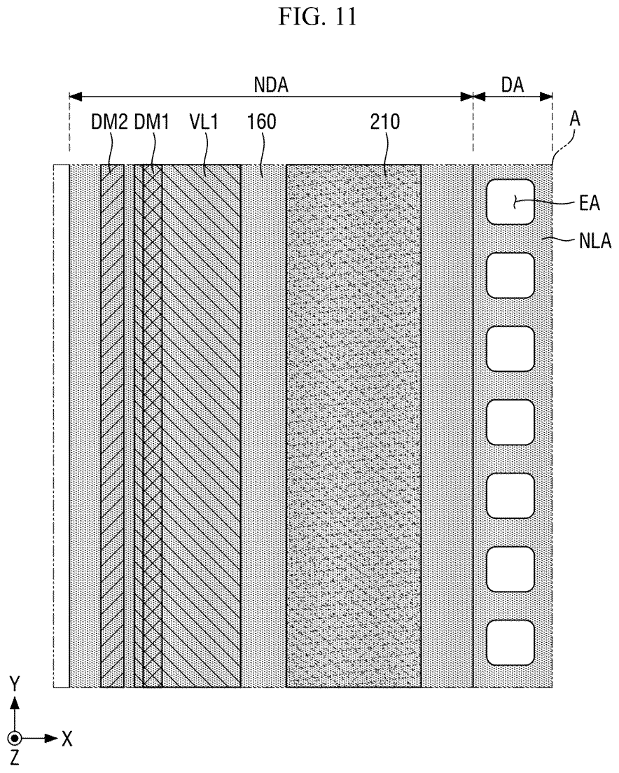

FIG. 11 is a schematic plan view of structures overlapping the bank structure 160 in FIG. 8.

Referring to FIG. 11, in a portion overlapping the display area DA, the bank structure 160 may be disposed in the non-emission area NLA and may completely surround the emission areas EA in plan view. In a portion overlapping the non-display area NDA, the bank structure 160 may completely cover the gate driver 210, the first power line VL1, the first dam DM1, and the second dam DM2 in plan view.

In plan view, the bank structure 160 disposed in the display area DA and the bank structure 160 disposed in the non-display area NDA may be integral.

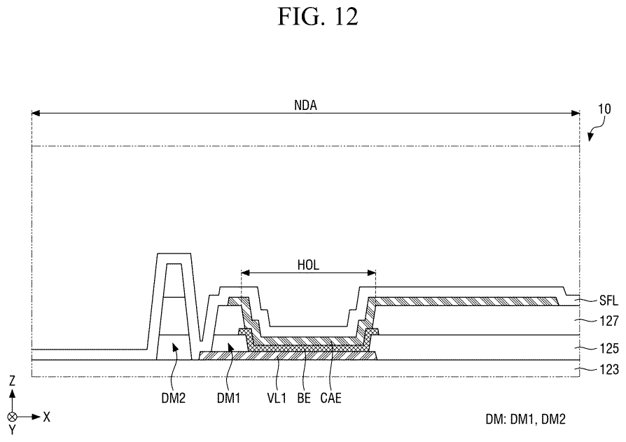

FIGS. 12 through 18 are schematic cross-sectional views illustrating a process of fabricating a display device 10 according to an embodiment in the non-display area NDA of FIG. 9. For ease of description, processes performed after a second interlayer insulating layer 123, a first via layer 125, a second via layer 127, a dam structure DM, a first power line VL1, a connection electrode BE, and a power connection electrode CAE are formed will be described in FIGS. 12 through 18. For example, the power connection electrode CAE and the first power line VL1 may be spaced apart from each other with the connection electrode BE interposed between them in a portion overlapping a hole HOL that penetrates the first via layer 125 and the second via layer 127. The connection electrode BE may be disposed on the first via layer 125 and may contact the first power line VL1 in the portion overlapping the hole HOL. The power connection electrode CAE may be disposed on the second via layer 127 and may contact the connection electrode BE in the portion overlapping the hole HOL. Accordingly, the connection electrode BE, the power connection electrode CAE, and the first power line VL1 may be electrically connected.

Referring to FIG. 12, a sacrificial layer SFL is formed on the entire surfaces of the second via layer 127, the power connection electrode CAE, and the dam structure DM. The sacrificial layer SFL may contact the power connection electrode CAE and the dam structure DM.

The sacrificial layer SFL may include an oxide semiconductor. For example, the sacrificial layer SFL may include at least one of indium gallium zinc oxide (IGZO), zinc tin oxide (ZTO), and indium tin oxide (ITO).

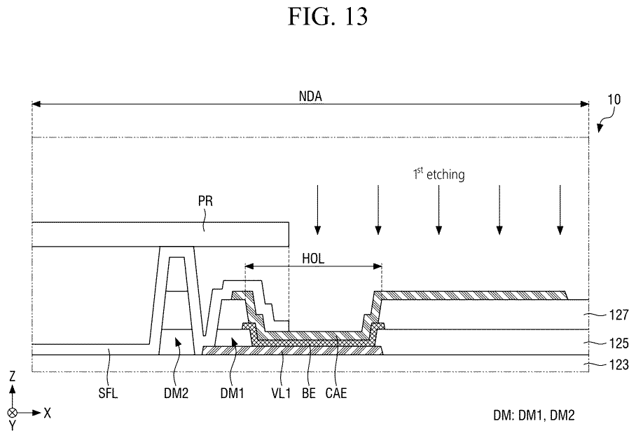

Referring to FIG. 13, a photoresist PR is formed to overlap the dam structure DM and a portion around the dam structure DM, and a first etching process is performed. For example, the first etching process may be performed as a wet etching process. In the current process, a portion of the sacrificial layer SFL which is overlapped by the photoresist PR may remain, and a portion of the sacrificial layer SFL which is not overlapped by the photoresist PR may be removed. Accordingly, a portion of the power connection electrode CAE which overlaps the second via layer 127 and the hole HOL may be exposed again.

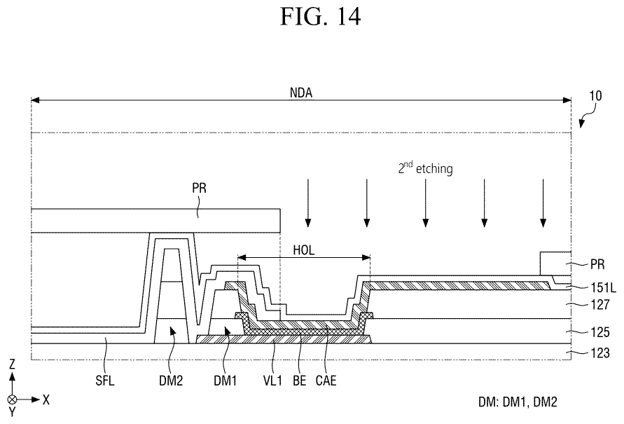

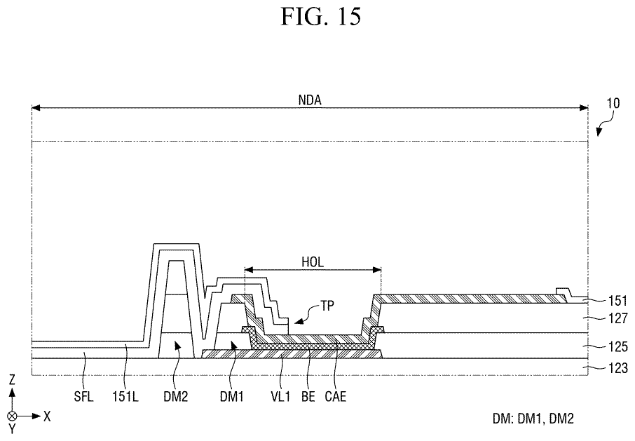

Referring to FIGS. 14 and 15, a pixel defining material layer 151L is formed on the entire surfaces of the remaining sacrificial layer SFL and the power connection electrode CAE exposed in the previous process. The pixel defining material layer 151L may contact the sacrificial layer SFL and the power connection electrode CAE.

A photoresist PR is formed on the dam structure DM and the portion around the dam structure DM, and a second etching process is performed. For example, the second etching process may be performed as a dry etching process. Since the second etching process is performed as a dry etching process, the pixel defining material layer 151L may be isotropically etched. Through the current process, a trench portion TP may be formed on a side surface of the sacrificial layer SFL and a side surface of the pixel defining material layer 151L in the portion overlapping the hole HOL.

In the current process, a portion of the pixel defining material layer 151L which is overlapped by the photoresist PR may remain, and a portion of the pixel defining material layer 151L which is not overlapped by the photoresist PR may be removed. Therefore, the sacrificial layer SFL of an embodiment may be covered by the pixel defining material layer 151L in a portion overlapping the non-display area NDA. In the current process, a portion of the power connection electrode CAE which overlaps the second via layer 127 and the hole HOL may be exposed again.

Through the above process, an end of the power connection electrode CAE on the second side in the first direction (X-axis direction) and an upper surface of the power connection electrode CAE may contact the sacrificial layer SFL and may be completely covered by the sacrificial layer SFL and the pixel defining material layer 151L. Accordingly, it is possible to solve corrosion defects of the power connection electrode CAE, the connection electrode BE, and the first power line VL1 caused by penetration of an etchant used in the fabrication process of the display device 10 according to the embodiment.

Through the current process, a pixel defining layer 151 which covers an end of the power connection electrode CAE on the first side in the first direction (X-axis direction) may be formed. Although not illustrated in FIG. 15, the pixel defining layer 151 which covers the end of the power connection electrode CAE on the first side in the first direction (X-axis direction) may be integral with the pixel defining layer 151 formed in the emission area EA illustrated in FIG. 9.

In an embodiment, the first etching process and the second etching process may be performed in combination. In this case, after the pixel defining material layer 151L is formed on the entire surface of the sacrificial layer SFL formed over the entire surface, a wet etching process and a dry etching process may be alternately performed to simultaneously etch a portion of the sacrificial layer SFL and a portion of the pixel defining material layer 151L.

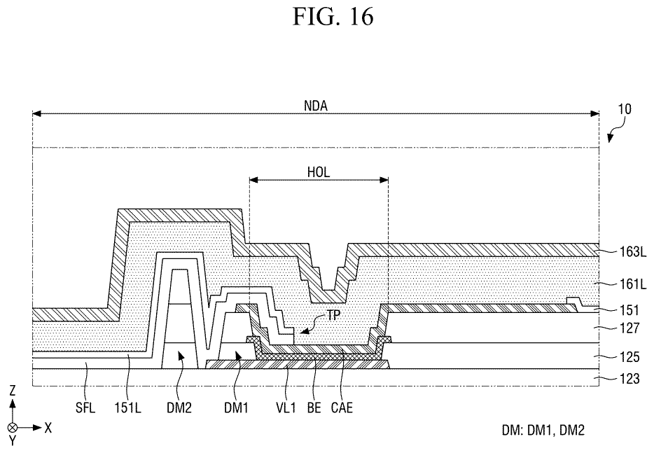

Referring to FIG. 16, a first bank material layer 161L and a second bank material layer 163L are sequentially stacked on the pixel defining material layer 151L and the power connection electrode CAE. The first bank material layer 161L and the second bank material layer 163L may be disposed on the entire surfaces of the pixel defining material layer 151L and the power connection electrode CAE. The first bank material layer 161L may contact the trench portion TP formed by the sacrificial layer SFL and the pixel defining material layer 151L and may completely cover the trench portion TP. The first bank material layer 161L may contact the upper surface of the power connection electrode CAE exposed through the previous process and may completely cover the upper surface of the power connection electrode CAE. Accordingly, it is possible to solve corrosion defects of the power connection electrode CAE, the connection electrode BE, and the first power line VL1 caused by penetration of an etchant used in the fabrication process of the display device 10 according to the embodiment.

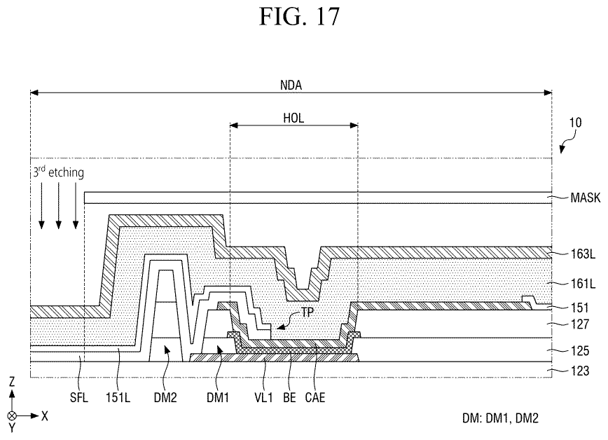

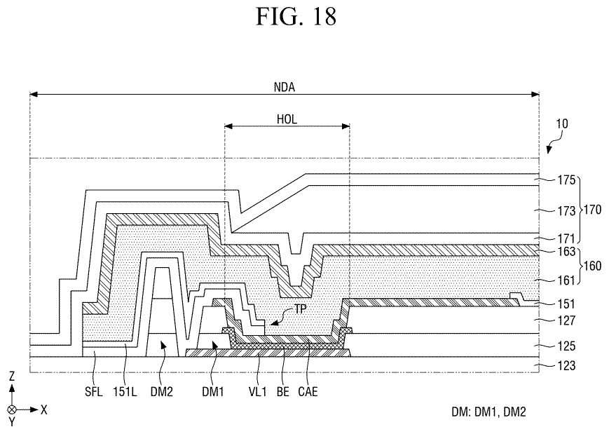

Referring to FIGS. 17 and 18, a mask MASK is formed in a portion overlapping the power connection electrode CAE and the dam structure DM, and a third etching process is performed to etch exposed portions of the pixel defining material layer 151L, the sacrificial layer SFL, the first bank material layer 161L and the second bank material layer 163L. For example, the third etching process may be performed as a dry etching process, but the disclosure is not limited thereto.

In the current process, in the portion overlapping the non-display area NDA, the pixel defining material layer 151L may be formed into the pixel defining layer 151 illustrated in FIG. 9, and the sacrificial layer SFL may be formed into a residual pattern 153. The first bank material layer 161L may be formed into a first bank layer 161, and the second bank material layer 163L may be formed into a second bank layer 163.

A thin-film encapsulation layer 170 may be formed by sequentially forming a first encapsulation layer 171, a second encapsulation layer 173, and a third encapsulation layer 175 on the second bank layer 163.

As described above, the display device 10 of the embodiment may include the residual pattern 153 and the pixel defining layer 151 which cover a portion of the power connection electrode CAE in the portion overlapping the non-display area NDA and may include the bank structure 160 which completely covers the power connection electrode CAE in the portion overlapping the non-display area NDA. Therefore, it is possible to solve corrosion defects of the power connection electrode CAE, the connection electrode BE, and the first power line VL1 caused by penetration of an etchant used in the fabrication process of the display device 10.

A display device of an embodiment may include, in a portion overlapping a non-display area, a power connection electrode which is connected to a power electrode and a pixel defining layer, a residual pattern and a bank structure which completely cover the power connection electrode. Therefore, it is possible to solve corrosion defects of the power connection electrode caused by a fabrication process of the display device.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure and as set forth in the following claims.

What is claimed is:

1. A display device comprising:
a display area comprising an emission area and a non-emission area and a non-display area surrounding the display area;
a substrate;
an anode disposed on the substrate in the emission area;
a pixel defining layer disposed on the substrate in the non-emission area and defining a first opening;
a bank structure disposed on the pixel defining layer and defining a second opening;
a residual pattern disposed between the anode and the pixel defining layer in the second opening in a direction perpendicular to the substrate;
a light emitting layer disposed on the anode and contacting the bank structure;
a cathode disposed on the light emitting layer and contacting the bank structure;
a power line disposed on the substrate in the non-display area;
a dam structure disposed on the power line; and
a power connection electrode disposed on the power line and the dam structure and spaced apart from the anode, wherein
a portion of the power connection electrode is covered by the residual pattern and the pixel defining layer, and
a side surface of the power connection electrode facing the dam structure contacts the residual pattern and is completely covered by the residual pattern and the pixel defining layer.

2. The display device of claim 1, wherein the bank structure comprises:
a first bank layer contacting the cathode; and
a second bank layer comprising a tip protruding more toward the emission area than a side surface of the first bank layer facing the first opening.

3. The display device of claim 2, wherein
the residual pattern overlapping the non-display area comprises a first side surface overlapping the power line in a direction perpendicular to the substrate, and
the first side surface contacts the first bank layer and is completely covered by the first bank layer.

4. The display device of claim 3, wherein the residual pattern overlapping the display area and the residual pattern overlapping the non-display area are spaced apart from each other.

5. The display device of claim 4, wherein the residual pattern overlapping the display area overlaps the tip of the second bank layer in the direction perpendicular to the substrate.

6. The display device of claim 2, wherein in a portion overlapping the non-display area, the pixel defining layer is disposed between the first bank layer and the residual pattern in the direction perpendicular to the substrate.

7. The display device of claim 6, wherein
the pixel defining layer overlapping the non-display area comprises a first side surface overlapping the power line in the direction perpendicular to the substrate, and
the first side surface contacts the first bank layer and is completely covered by the first bank layer.

8. The display device of claim 7, wherein the pixel defining layer overlapping the display area and the pixel defining layer overlapping the non-display area are spaced apart from each other.

9. The display device of claim 1, wherein the residual pattern and the pixel defining layer overlapping the non-display area completely cover the dam structure.

10. The display device of claim 1, wherein
the side surface of the power connection electrode facing the dam structure is completely covered by the bank structure, and
the bank structure completely covers the dam structure.

11. The display device of claim 2, wherein
the power connection electrode comprises a first surface facing the bank structure, and
the first surface comprises a first part contacting the residual pattern and a second part contacting the first bank layer.

12. The display device of claim 11, wherein the first surface is completely covered by the residual pattern and the first bank layer.

13. The display device of claim 12, wherein
the first part overlaps the pixel defining layer and the bank structure in the direction perpendicular to the substrate, and
the second part does not overlap the pixel defining layer and the residual pattern in the direction perpendicular to the substrate.

14. The display device of claim 2, wherein a voltage applied to the power line is applied to the cathode through the power connection electrode and the first bank layer.

15. The display device of claim 2, further comprising:
an organic pattern disposed on the tip of the second bank layer, the organic pattern and the light emitting layer comprising a same material, the organic pattern spaced apart from the light emitting layer; and
an electrode pattern disposed on the organic pattern, the electrode pattern and the cathode comprising a same material, the electrode pattern spaced apart from the cathode.

16. The display device of claim 15, further comprising:
a thin-film encapsulation layer disposed on the cathode, the electrode pattern and the bank structure,
wherein the thin-film encapsulation layer overlaps the display area and the non-display area and comprises at least one organic material layer and at least one inorganic material layer.

17. A display device comprising:
a display area comprising an emission area and a non-emission area and a non-display area surrounding the display area;
a substrate;
a pixel defining layer disposed on the substrate in the non-emission area and defining a first opening;
a bank structure disposed on the pixel defining layer and defining a second opening;
a power line disposed on the substrate in the non-display area and surrounding the display area;
a dam structure disposed on the power line and surrounding the display area; and
a power connection electrode covering the power line and the dam structure, wherein
a residual pattern and a pixel defining layer are disposed between the bank structure and the power connection electrode in a direction perpendicular to the substrate, and
the bank structure disposed in the non-emission area and the bank structure disposed in the non-display area are integral in plan view.

18. The display device of claim 17, wherein the bank structure completely covers the power connection electrode and the dam structure in plan view.

19. The display device of claim 18, wherein
the second opening completely surrounds the first opening in plan view, and
the bank structure completely surrounds the second opening in plan view.

20. A method of fabricating a display device, the method comprising:
forming a substrate which comprises a display area and a non-display area surrounding the display area, forming a power line on the substrate in the non-display area;
forming a dam structure and a power connection electrode, connected to the power line, on the power line, and forming a sacrificial layer covering entire surfaces of the power connection electrode and the dam structure;
forming a photoresist around the dam structure, exposing a portion of the power connection electrode again by removing a portion of the sacrificial layer by performing a first etching process, and forming a pixel defining material layer on entire surfaces of the sacrificial layer and the power connection electrode;
forming a photoresist around the dam structure, exposing a portion of the power connection electrode again by removing a portion of the pixel defining material layer by performing a second etching process, and forming a bank structure on entire surfaces of the pixel defining material layer and the power connection electrode; and
forming a mask in a portion overlapping the dam structure and the power connection electrode and forming a pixel defining layer and a residual pattern, covering a portion of the power connection electrode and the dam structure, by removing the bank structure, the pixel defining material layer and the sacrificial layer in an exposed portion by performing a third etching process, wherein
a side surface of the power connection electrode facing the dam structure contacts the residual pattern, and
the power connection electrode is completely covered by the residual pattern and the bank structure.
